(19) United States
(12) Patent Application Publication
(10) Pub. No.: US 2013/0193492 A1
(43) Pub. Date: Aug. 1, 2013

(54) SILICON CARBON FILM STRUCTURE AND METHOD

(71) Applicants: THOMAS N. ADAM, Albany, NY (US); Kangguo Cheng, Albany, NY (US); Hong He, Albany, NY (US); Ali Khakifirooz, San Jose, CA (US); Jinghong Li, Hopewell Junction, NY (US); Alexander Reznicek, Hopewell Junction, NY (US)

(72) Inventors: THOMAS N. ADAM, Albany, NY (US); Kangguo Cheng, Albany, NY (US); Hong He, Albany, NY (US); Ali Khakifirooz, San Jose, CA (US); Jinghong Li, Hopewell Junction, NY (US); Alexander Reznicek, Hopewell Junction, NY (US)

(73) Assignee: International Business Machines Corporation, Armonk, NY (US)

(21) Appl. No.: 13/360,823

(22) Filed: Jan. 30, 2012

(51) Int. Cl. H01L 29/78; H01L 21/20

(52) U.S. Cl. 257/288; 438/479; 257/E21.09; 257/E29.255

(57) ABSTRACT

An improved silicon carbon film structure is disclosed. The film structure comprises multiple layers of silicon carbon and silicon. The multiple layers form stress film structures that have increased substitutional carbon content, and serve to induce stresses that improve carrier mobility for certain types of field effect transistors.

### FIELD OF THE INVENTION

The present invention relates generally to semiconductor fabrication, and more particularly, to an improved method and structure for fabricating silicon carbon films.

### BACKGROUND OF THE INVENTION

Stress-inducing films are used in the fabrication of field effect transistors (FETs) to increase performance by improving carrier mobility. For N-type FETs (NFETs), tensile stress on the channel improves electron mobility. Silicon-carbon (SiC) films may be used to create the desired tensile stress which is useful for improving the performance of NFETs. The amount of stress created increases with the substitutional carbon concentration in the SiC film. Forming SiC with C concentrations exceeding one percent is difficult. The material matrix has a very low solubility limit, and under practical metastable deposition conditions (600 C and below) the film quickly grows in an amorphous phase at slightly increased carbon concentrations, which renders the material unusable for stress-inducing purposes. Therefore, it is desirable to have an improved method and structure for fabricating SiC films.

### SUMMARY

In one embodiment, a method of inducing stress in a silicon substrate is provided. The method comprises growing a first layer of silicon carbon on the silicon substrate, depositing a silicon layer on the first layer of silicon carbon, and growing a second layer of silicon carbon on the silicon layer, thereby forming a stress film structure. In another embodiment, a method of inducing stress in a silicon substrate is provided. The method comprises growing a first layer of silicon carbon on the silicon substrate, depositing a silicon layer on the first layer of silicon carbon, doping the silicon layer with phosphorous, and growing a second layer of silicon carbon on the silicon layer. In another embodiment, a field effect transistor is provided. The field effect transistor comprises a silicon substrate, a gate disposed on the silicon substrate, a channel region disposed under the gate, a first stress film cavity disposed in the silicon substrate on a first side of the channel region, a second stress film cavity disposed in the silicon substrate on a second side of the channel region, and a plurality of alternating layers of silicon carbon and silicon disposed within the first stress film cavity and the second stress film cavity.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

Often, similar elements may be referred to by similar numbers in various figures (FIGs) of the drawing, in which case typically the last two significant digits may be the same, the most significant digit being the number of the drawing figure (FIG).

FIG. 1 shows a semiconductor structure at a starting point for formation of a film structure in accordance with an embodiment of the present invention.

FIG. 2 shows a detailed view of a subsequent process step of forming a silicon carbon film.

FIG. 3 shows a detailed view of a subsequent process step of forming a silicon film.

FIG. 4 shows a detailed view of a subsequent process step of forming an additional silicon carbon film.

FIG. 5 shows a semiconductor structure in accordance with an embodiment of the present invention.

FIG. 6 is a flowchart indicating process steps for an embodiment of the present invention.

FIG. 7 shows a block diagram of an exemplary design flow.

### DETAILED DESCRIPTION

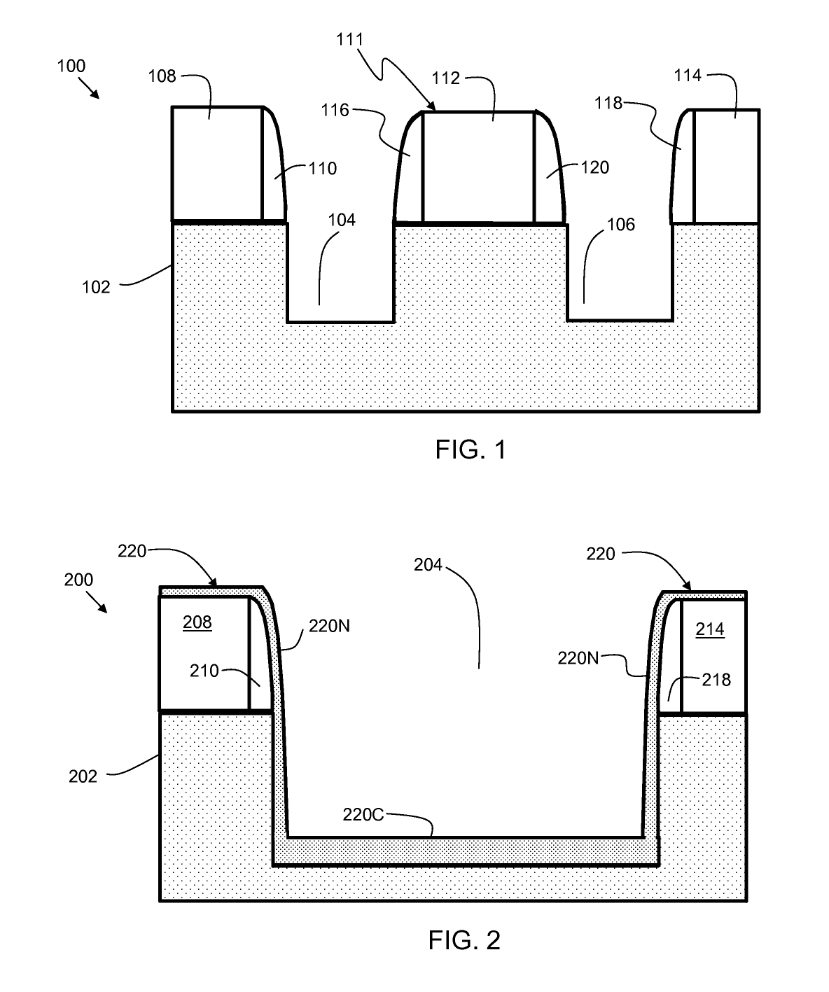

FIG. 1 shows a semiconductor structure 100 at a starting point for formation of a film structure in accordance with an embodiment of the present invention. Semiconductor structure 100 comprises a silicon substrate 102. Disposed on silicon substrate 102 are a plurality of transistor gates 108, 112, and 114. Note that only gate 112 is shown in its entirety, and only a portion of gates 108 and 114 are shown, for the sake of illustrative clarity. Gate 112 has a nitride spacer 116 disposed on one side of gate 112, and another nitride spacer 120 disposed on the other side of gate 112. Gate 112 may be comprised of polysilicon. Gate 108 has nitride spacer 110 disposed on one side. Gate 108 is only partially shown in FIG. 1, and thus, while a corresponding nitride spacer is present on the other side of gate 108, it is not shown in FIG. 1. Similarly, gate 114 has nitride spacer 118 disposed on one side. Gate 114 is only partially shown in FIG. 1, and thus, while a corresponding nitride spacer is present on the other side of gate 114, it is not shown in FIG. 1. A stress film structure cavity 104 is formed in silicon substrate 102 on one side of gate 112, and a similar stress film structure cavity 106 is formed in silicon substrate 102 on the other side of gate 112. The stress film structure cavities may be formed by a reactive ion etch (RIE). In subsequent steps, a stress film structure is formed in the stress film structure cavities to induce performance-enhancing stresses to increase carrier mobility for the field effect transistor 111.

FIG. 2 shows a detailed view of a semiconductor structure 200 after a subsequent process step of forming a silicon carbon film 220. As stated previously, similar elements may be referred to by similar numbers in various figures of the drawing, in which case typically the last two significant digits may be the same, the most significant digit being the number of the drawing figure. For example, spacer 210 of FIG. 2 is similar to spacer 110 of FIG. 1. Furthermore, for clarity, some reference numbers may be omitted in certain drawings. In this view, only one stress film structure cavity 204 is shown. Silicon carbon film 220 is grown on semiconductor structure 200. In one embodiment, the silicon carbon film 220 is formed in a UHV-CVD (Ultra-high vacuum chemical vapor deposition) tool. In one embodiment, a methylsilane gas (MMS) is used as a precursor gas to provide carbon. The flow of the MMS gas may be adjusted to control the amount of carbon present in silicon carbon film 220. In one embodiment, the methylsilane is administered at a flow rate ranging from about 35 sccm to about 100 sccm. In one embodiment, silicon carbon film 220 contains between 1.5% and 3.5% carbon, where the carbon is substitutional carbon (and hence, contributes to the performance-enhancing tensile stress). Note that substitutional carbon in silicon differs from “C-doped silicon” in that C-doped silicon generally refers to total carbon, which is the sum of substitutional and non-substitutional carbon.

The silicon carbon film 220 induces tensile stress that is effective in increasing electron mobility for N-FETs (N type field effect transistors). However, the carbon film 220 can not be grown too thick (e.g. beyond 100 angstroms), or defects will significantly increase to the point where the desired stresses are not being generated. Furthermore, only substitutional carbon (carbon in the lattice) in the silicon carbon (SiC) film contributes to tensile stress. While the flow of the MMS precursor gas may increase the total carbon content of the film, after a certain concentration, additional carbon atoms are non-substitutional (outside of the lattice structure of the film) and hence, do not further increase tensile stress. Therefore, the ability to achieve carrier mobility performance has heretofore been limited by the nature of the SiC film properties. In one embodiment, the thickness of film 220 ranges from about 8 angstroms to about 28 angstroms. SiC film 220 has two portions, a crystalline portion 220C that is in contact with silicon substrate 202, and a non-crystalline portion 220N that is in contact with the nitride spacers and polysilicon gates. In a subsequent process step, a selective etch that only etches amorphous silicon films, and does not substantially remove crystalline silicon films, may be used to remove the silicon carbon film portion 220N.

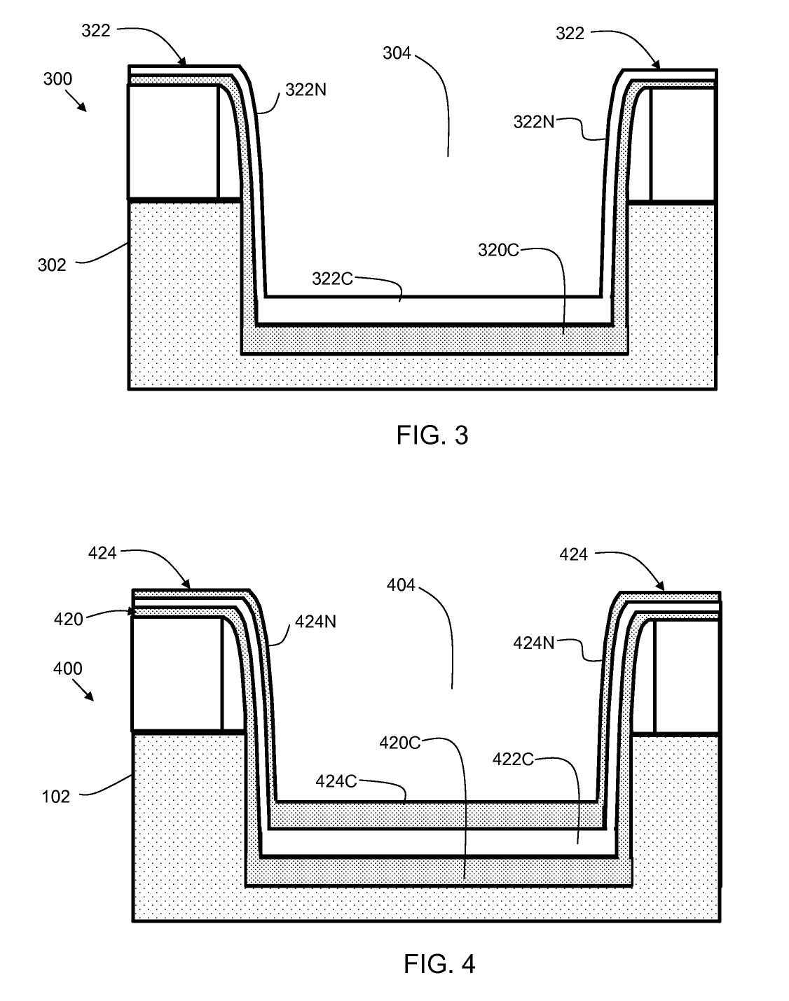

FIG. 3 shows a detailed view of a semiconductor structure 300 after a subsequent process step of depositing a silicon film 322 over SiC film 320. As stated previously, if the SiC film 320C is grown too thick, excessive defects prevent the desired increase in stress from the SiC film. However, the inventors have found that if the growth of the SiC film 320C is stopped before it gets too thick (e.g. in a range from about 8 angstroms to about 28 angstroms), and then a thin film of silicon 322 is deposited on the SiC film 320C, the silicon film 322C rearranges itself to a state suitable for growing crystalline SiC films. In one embodiment, the silicon film 322C has a thickness ranging from about 8 angstroms to about 28 angstroms. The silicon film 322C serves as a terminating layer for the SiC layer 320C, to provide a surface for growing another SiC film. The silicon film 322C may be deposited via a UHV-CVD process. The UHV-CVD process provides an advantage of lower process temperatures. Lower process temperatures may serve to reduce defects and improve overall effective yield during fabrication. In one embodiment, the silicon film 322 is deposited at a temperature ranging from about 550 degrees Celsius to about 650 degrees Celsius.

In an alternative embodiment, silicon carbon film 220 also contains phosphorous, and may be referred to as a SiC:P film. The use of phosphorous may be used to control certain properties of the silicon and silicon carbon, such as conductivity. In the case where phosphorous is also desired, the subsequent silicon film 322 may be doped with phosphorous with a dopant concentration in the range of about 1E20 atoms/cm3 to about 5E20 atoms/cm3. In another alternative embodiment, silicon carbon film 220 also contains arsenic.

FIG. 4 shows a detailed view of a semiconductor structure 400 after a subsequent process step of forming an additional silicon carbon film layer 424. The portion of silicon carbon film 424C is crystalline, since it is grown on the previously deposited silicon layer 422C. Hence, within stress film structure cavity 404 are two layers of crystalline silicon carbon: layer 424C, and layer 420C. Together, these two crystalline silicon carbon layers contribute more tensile stress than would be the case with layer 420C alone. Furthermore, the additional silicon carbon film layer 424 is grown without any “etch back” of the previously grown silicon carbon film layer 420. In a prior art process, the silicon carbon layer films may be grown until the point of excessive defects, and then etched back to remove the defects. In doing so, a portion of crystalline film may also be removed, which is counterproductive to the end goal of creating additional stress for enhanced carrier mobility. Embodiments of the present invention do not perform such an etch back, and thus, with embodiments of the present invention, the time required to fabricate a silicon carbon film structure in the stress film structure cavity 404 is considerably reduced as compared with prior art methods. The cycle of forming alternating layers of silicon carbon and silicon may be repeated multiple times (e.g. 50 to 100 cycles or more) to achieve an improved stress film structure. In one embodiment, the stress film structure may have between 50 to 100 film layers. Other embodiments may have more than 100 film layers. In one embodiment, the thickness of the silicon carbon layers 220 and the thickness of the silicon layers 322 are equal or nearly equal. In this way, as the process of forming layers of silicon carbon followed by silicon is repeated to form a stress film structure, the ratio of silicon to silicon carbon is approximately equal. In one embodiment, the percentage of silicon carbon in the stress film structure ranges from about 45 percent to about 55 percent. In one embodiment, the thickness of each silicon carbon layer is substantially the same. In one embodiment, the standard deviation of the thickness of each silicon carbon layer ranges from about 2.9% to about 3.1% of the average thickness of the plurality of silicon carbon layers.

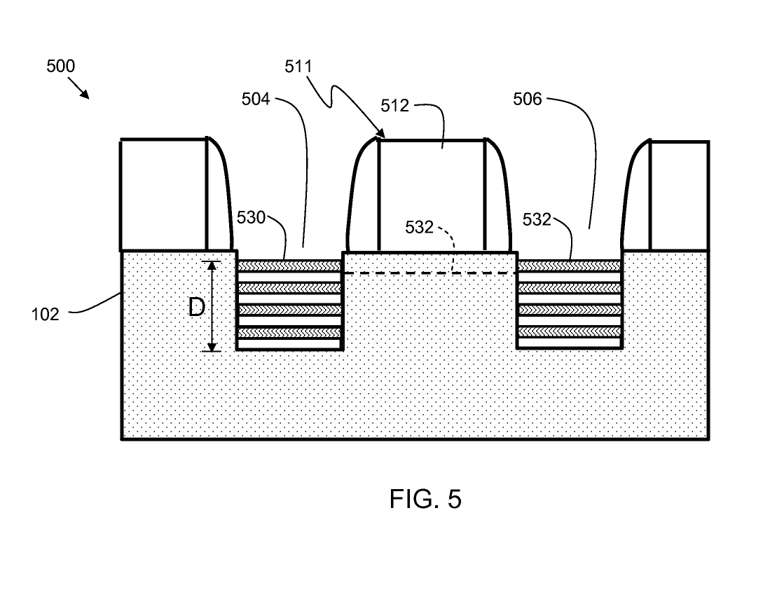

FIG. 5 shows a semiconductor structure 500 in accordance with an embodiment of the present invention. Semiconductor structure 500 comprises stress film structure 530 disposed in stress film structure cavity 504 and stress film structure 532 disposed in stress film structure cavity 506. Each stress film structure is comprised of alternating layers of a silicon carbon film and a silicon film. While for the sake of clarity, only a few layers of silicon carbon and silicon are shown in stress film structure 530 and stress film structure 532, in practice, the stress film structures 530 and 532 may have between 50 to 100 film layers. Furthermore, also for clarity, the layers of stress film structures 530 and 532 are shown as being of uniform size, since the sidewall portions (the “N” portions in FIG. 4, such as 424N) are much thinner than the width of the film layers, and may be considered as negligible. Other embodiments may have more than 100 film layers, and the depth D of the stress film structures may range from about 50 nanometers to 200 nanometers in some embodiments. The non-crystalline portions of the silicon carbon films and silicon films (that were disposed on the spacers and gates of transistors) are removed via a selective etch process that removes non-crystalline silicon films while leaving crystalline silicon films substantially intact. In one embodiment, the selective etch process is performed with HCl (hydrochloric acid). The stress film structures 530 and 532 disposed within the stress film structure cavities 504 and 506, respectively, serve to induce performance-enhancing stresses to increase carrier mobility for the field effect transistor 511.

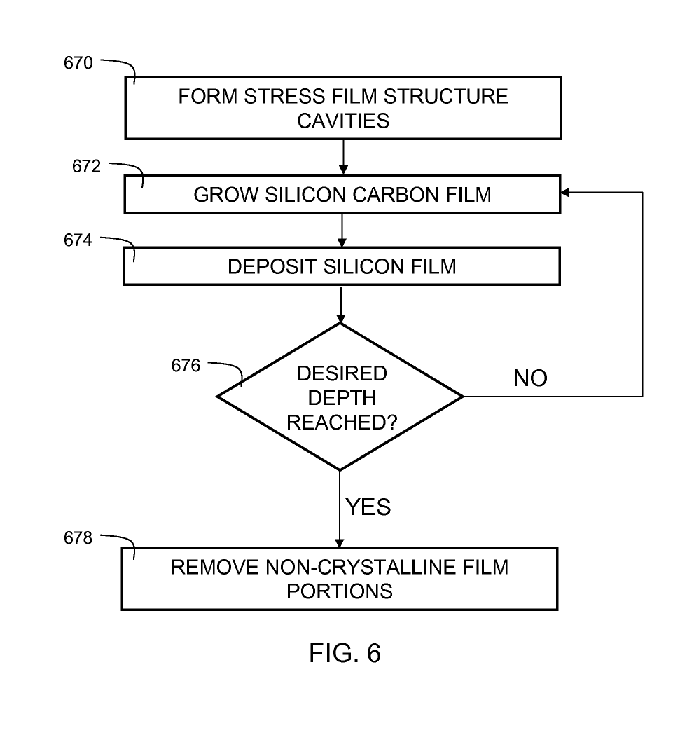

FIG. 6 is a flowchart indicating process steps for an embodiment of the present invention. In process step 670, stress film structure cavities are formed (see 104 and 106 of FIG. 1). In process step 672, a silicon carbon film is grown in the stress film structure cavities (see 220 of FIG. 2). In process step 674, a silicon film is deposited on the silicon carbon film (see 322 of FIG. 3). In process step 676, an evaluation is made to determine of the stress film structure (comprised of the alternating layers of silicon carbon and silicon) is of the desired depth. If not, then process steps 672 and 674 are repeated as necessary until the desired depth is reached. Each iteration of steps 672 and 674 is referred to as a “cycle.” Then, in process step 678, the non-crystalline film portions are removed (see 500 of FIG. 5).

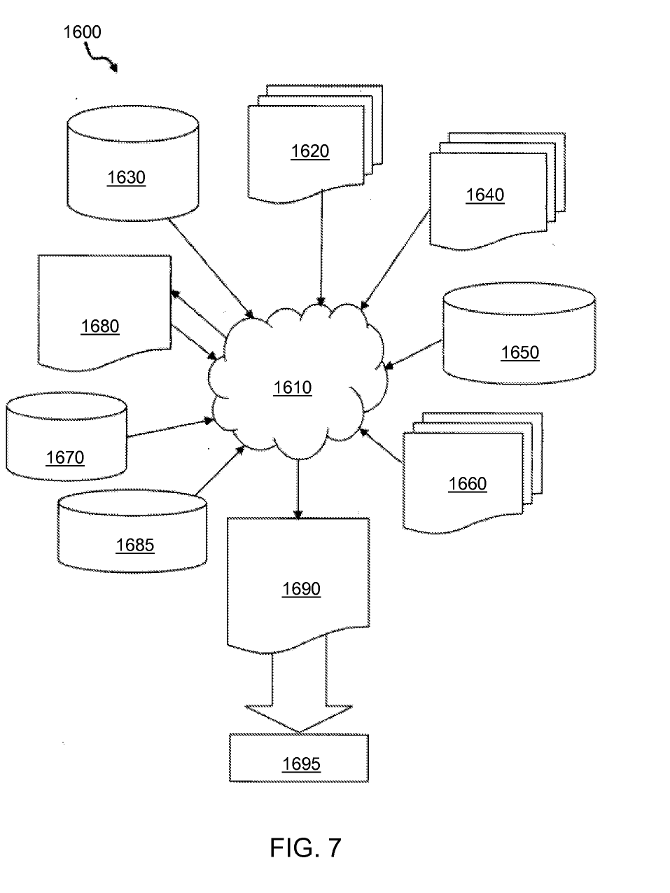

FIG. 7 shows a block diagram of an exemplary design flow 1600 used for example, in semiconductor IC logic design, simulation, test, layout, and manufacture. Design flow 1600 includes processes, machines and/or mechanisms for processing design structures or devices to generate logically or otherwise functionally equivalent representations of the design structures and/or devices described above and shown in FIGS. 1-5. The design structures processed and/or generated by design flow 1600 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 1600 may vary depending on the type of representation being designed. For example, a design flow 1600 for building an application specific IC (ASIC) may differ from a design flow 1600 for designing a standard component or from a design flow 1600 for instantiating the design into a programmable array, for example a programmable gate array (PGA) or a field programmable gate array (FPGA) offered by Altera® Inc. or Xilinx® Inc.

FIG. 7 illustrates multiple such design structures including an input design structure 1620 that is preferably processed by a design process 1610. Design structure 1620 may be a logical simulation design structure generated and processed by design process 1610 to produce a logically equivalent functional representation of a hardware device. Design structure 1620 may also or alternatively comprise data and/or program instructions that when processed by design process 1610, generate a functional representation of the physical structure of a hardware device. Whether representing functional and/or structural design features, design structure 1620 may be generated using electronic computer-aided design (ECAD) such as implemented by a core developer/designer. When encoded on a machine-readable data transmission, gate array, or storage medium, design structure 1620 may be accessed and processed by one or more hardware and/or software modules within design process 1610 to simulate or otherwise functionally represent an electronic component, circuit, electronic or logic module, apparatus, device, or system such as those shown in FIGS. 1-5. As such, design structure 1620 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 1610 preferably employs and incorporates hardware and/or software modules for synthesizing, translating, or otherwise processing a design/simulation functional equivalent of the components, circuits, devices, or logic structures shown in FIGS. 1-5 to generate a Netlist 1680 which may contain design structures such as design structure 1620. Netlist 1680 may comprise, for example, compiled or otherwise processed data structures representing a list of wires, discrete components, logic gates, control circuits, I/O devices, models, etc. that describes the connections to other elements and circuits in an integrated circuit design. Netlist 1680 may be synthesized using an iterative process in which netlist 1680 is resynthesized one or more times depending on design specifications and parameters for the device. As with other design structure types described herein, netlist 1680 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 1610 may include using a variety of inputs; for example, inputs from library elements 1630 which may house a set of commonly used elements, circuits, and devices, including models, layouts, and symbolic representations, for a given manufacturing technology (e.g., different technology nodes, 32 nm, 45 nm, 90 nm, etc.), design specifications 1640, characterization data 1650, verification data 1660, design rules 1670, and test data files 1685 (which may include test patterns and other testing information). Design process 1610 may further include, for example, standard circuit design processes such as timing analysis, verification, design rule checking, place and route operations, etc. One of ordinary skill in the art of integrated circuit design can appreciate the extent of possible electronic design automation tools and applications used in design process 1610 without deviating from the scope and spirit of the invention. The design structure of the invention is not limited to any specific design flow.

Design process 1610 preferably translates an embodiment of the invention as shown in FIGS. 1-5, along with any additional integrated circuit design or data (if applicable), into a second design structure 1690. Design structure 1690 resides on a storage medium in a data format used for the exchange of layout data of integrated circuits (e.g. information stored in a GDSII (GDS2), GL1, OASIS, or any other suitable format for storing such design structures). Design structure 1690 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as described above with reference to FIGS. 1-5. Design structure 1690 may then proceed to a stage 1695 where, for example, design structure 1690: proceeds to tape-out, is released to manufacturing, is released to a mask house, is sent to another design house, is sent back to the customer, etc.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

What is claimed is:

1. A method of inducing stress in a silicon substrate, comprising:
growing a first layer of silicon carbon on the silicon substrate;
depositing a silicon layer on the first layer of silicon carbon; and
growing a second layer of silicon carbon on the silicon layer, thereby forming a stress film structure.

2. The method of claim 1, wherein depositing a silicon layer on the first layer of silicon carbon is performed via ultra high vacuum chemical vapor deposition.

3. The method of claim 2, wherein depositing a silicon layer on the first layer of silicon carbon is performed at a temperature ranging from about 550 degrees Celsius to about 650 degrees Celsius.

4. The method of claim 2, wherein growing a first layer of silicon carbon on the silicon substrate comprises growing a silicon carbon layer having a thickness ranging from about 8 angstroms to about 28 angstroms.

5. The method of claim 2, wherein growing a first layer of silicon carbon on the silicon substrate further comprises administering a precursor gas of methylsilane into an ultra high vacuum chemical vapor deposition tool.

6. The method of claim 5, wherein administering a precursor gas of methylsilane into an ultra high vacuum chemical vapor deposition tool comprises administering methylsilane at a flow rate ranging from about 35 sccm to about 100 sccm.

7. The method of claim 1, further comprising repeating for 50 to 100 times, a cycle of:
depositing an additional silicon layer on an exposed layer of silicon carbon; and
growing an additional layer of silicon carbon on the additional silicon layer.

8. The method of claim 7, wherein growing a first layer of silicon carbon on the silicon substrate further comprises forming regions of non-crystalline silicon carbon and non-crystalline silicon on non-crystalline surfaces; and
removing the non-crystalline silicon carbon and non-crystalline silicon with an etch process after completion of performing the repeated cycles of depositing an additional silicon layer and growing an additional layer of silicon carbon on the additional silicon layer.

9. The method of claim 8, wherein removing the non-crystalline silicon carbon and non-crystalline silicon with an etch process comprises performing an etch with hydrochloric acid.

10. The method of claim 7, wherein the percentage of silicon carbon in the stress film structure ranges from about 45 percent to about 55 percent.

11. A method of inducing stress in a silicon substrate, comprising:
growing a first layer of silicon carbon on the silicon substrate;
depositing a silicon layer on the first layer of silicon carbon;
doping the silicon layer with phosphorous; and
growing a second layer of silicon carbon on the silicon layer.

12. The method of claim 11, further comprising repeating for 50 to 100 times, a cycle of:
depositing an additional silicon layer on an exposed layer of silicon carbon;
doping the additional silicon layer with phosphorous; and
growing an additional layer of silicon carbon on the silicon layer.

13. The method of claim 11, further comprising repeating for 50 to 100 times, a cycle of:
depositing an additional silicon layer on an exposed layer of silicon carbon;
doping the additional silicon layer with arsenic; and
growing an additional layer of silicon carbon on the silicon layer.

14. A field effect transistor comprising:
a silicon substrate;
a gate disposed on the silicon substrate;
a channel region disposed under the gate;
a first stress film cavity disposed in the silicon substrate on a first side of the channel region;
a second stress film cavity disposed in the silicon substrate on a second side of the channel region; and
a plurality of alternating layers of silicon carbon and silicon disposed within the first stress film cavity and the second stress film cavity.

15. The field effect transistor of claim 14, wherein each silicon layer is doped with phosphorous.

16. The field effect transistor of claim 15, wherein each silicon layer has a phosphorous dopant concentration ranging from about 1E20 atoms per cubic centimeter to about 5E20 atoms per cubic centimeter.

17. The field effect transistor of claim 14, wherein each layer of silicon carbon has a thickness ranging from about 8 angstroms to about 28 angstroms.

18. The field effect transistor of claim 17, wherein each layer of silicon has a thickness ranging from about 8 angstroms to about 28 angstroms.

19. The field effect transistor of claim 18, wherein the standard deviation of the thickness of each silicon carbon layer ranges from about 2.9% to about 3.1% of the average thickness of the plurality of silicon carbon layers.

20. The field effect transistor of claim 19, wherein the plurality of silicon carbon layers comprises between 50 layers and 100 layers.
